(19) United States
(12) Patent Application Publication
(10) Pub. No.: US 2016/0155865 A1
(43) Pub. Date: Jun. 2, 2016

(54) SOLAR CELL

(71) Applicant: SOLARWORLD INNOVATIONS GMBH, Freiberg (DE)

(72) Inventors: Bernd BITNAR, Bannewitz (DE); Gunter ERFURT, Freiberg (DE); Stefan STECKEMETZ, Freiberg (DE)

(73) Assignee: SOLARWORLD INNOVATIONS GMBH, Freiberg (DE)

(21) Appl. No.: 14/947,302

(22) Filed: Nov. 20, 2015

(30) Foreign Application Priority Data
Dec. 2, 2014 (DE) DE102014224679.2

(51) Int. Cl. H01L 31/0224; H01L 31/02

(52) U.S. Cl. CPC H01L 31/022433; H01L 31/0201

(57) ABSTRACT

A solar cell with a semiconductor body and with a contact layout for electrically connecting a surface of the semiconductor body, including: a plurality of current collecting contact fingers, which are disposed substantially parallel to each other, wherein the contact finger respectively has a line resistance of at least 100 Ω/m, a plurality of busbars, which are electrically connected to the contact fingers, and at least one cell connector continuously connecting the busbar, wherein the contact fingers and the busbar are dimensioned, particularly in terms of the material properties thereof, layout on the semiconductor body thereof, width and layer thickness thereof, that the contact layout has a series resistance of maximum 1 Ωcm².

### FIELD OF INVENTION

The present invention relates to a solar cell.

### TECHNICAL BACKGROUND

The invention relates to a solar cell having an electrical contact layout. Even though, the problem underlying the present invention is explained in the following with reference to a solar cell with a front-side contact layout, it is not restricted to that but can be extended to any randomly disposed and configured solar cells-contact layouts.

Generally, a front-side contact layout includes a front contact, which makes an electrical metal-semiconductor contact with the semiconductor material, and at least one cell connector electrically connected to this. The front contact includes current collecting contact fingers and one or more busbars electrically connected to the contact fingers. The cell connectors are electrically connected to the current collecting rail and connected on the entire surface. Such a front-side contact layout is described, e.g. in the DE 10 2011 055 561 A1.

In a conventional solar cell, the front-side contact layout includes a plurality of contact fingers extending parallel to each other, approximately 100 μm wide and generally 1 to 3 extend perpendicular to this, a much wider busbars with a width of approximately 2 mm. The cell connectors are configured generally somewhat narrower than the corresponding busbars and for the purpose of electrically connecting several solar cells to a module.

In order to achieve the maximum energy efficiency in a solar cell, a largest possible surface of the solar cell should contribute in photovoltaic power generation.

The problem is that those areas of the solar cells surfaces, which are covered by the front-side contact layout, are thereby shadowed due to the sunlight and thus cannot contribute to power generation anymore, which overall reduces the efficiency of the solar cell. The so-called shadow effects caused by the contact are referred to here. Thus, there is a requirement to design the contact fingers and busbars of the front-side contact layout on the entire surface, such that they cover the minimum surface of the front side of the solar cell.

A first approach would be to increase the distances of the contact fingers and busbars and/or to reduce their number. However, this is possible only to a very limited extent, because then it is not guaranteed that all charge carriers generated in the semiconductor by photo effect are absorbed over the front-side contact layout, which overall reduces the efficiency of the solar cell.

A second approach would be to reduce the width of the contact fingers or, optionally even of the busbars. The problem with this approach is that as a result, their resistance increases, which in turn increases the power loss and reduces the efficiency of the solar cell. In particular, the line resistance of a contact finger should be as low as possible, so that their resistive losses do not impair the efficiency of the solar cell too much. The corresponding context results from the Ohm's Law, which implies that at constant voltage, an increase in resistance causes a corresponding reduced current. Thus, the contact fingers and the busbars cannot be randomly configured narrow. Typically, the line resistance of a contact finger of a solar cell having three busbars known today is approximately up to 60 Ω/m.

Accordingly, in view of optimizing the efficiency of a solar cell, it is important to ensure that a design of a front-side contact layout is found, which provides a least possible shadow caused by the contact while keeping the least possible line resistance of the contact finger and busbars.

Another aspect is an appropriate selection of material of the front-side contact layouts. Contact layouts should be made of an excellent electric conducting material, such as Silver, Aluminum, Copper, etc. Silver is excellently suitable, because it has a higher conductivity in comparison to many other materials, which in turn is advantageous for the line resistance and thereby for the efficiency of the contact layouts made of Silver. However, this is at the expense of the material and manufacturing costs, because contact layouts made of Silver are much more costly in comparison to other materials. Thus, a reduction of the line resistance by an increased cross-section is always an obstacle due to an increased material and Silver consumption and so higher material costs. In practice, a more or less good compromise is sought until now between the material costs, shadowing and electrical resistance.

### SUMMARY OF THE INVENTION

Against this background, the object underlying the present invention is to provide a solar cell with reduced manufacturing costs and/or reduced resistive losses.

In accordance with the invention, this object is accomplished by a solar cell according to claim 1.

Accordingly, a solar cell is provided having a semiconductor body and a contact layout for electrically connecting the surface of the semiconductor body, comprising: a plurality of current collecting contact fingers, which are disposed substantially parallel to each other, wherein the contact finger has a respective line resistance of at least 100 Ω/m, a plurality of busbars, which are electrically connected to the contact fingers, wherein the contact fingers and the busbars, particularly in terms of their material properties, their layout on the semiconductor body, their width and their layer thickness are dimensioned such that the contact layout has a series resistance of maximum 1 Ωcm².

The knowledge of the present invention is that present-day solar cells-contact layouts have only one or at least very few busbars. The idea of the present invention now is to substantially increase the number of the busbars used, however without increasing the resulting shadowing caused by the contact.

By increasing the number of the busbars, the busbars and the contact fingers can be configured significantly narrower with at least the same electrical conductivity. By using an increased number of busbars, their distance from each other also reduces. Therefore, the stretch—which the charge carriers must cover to reach the comparatively high-ohmic contact fingers—reduces, which ensures an increase in the efficiency.

The width of the contact finger is lower such that their line resistance increases to at least 100 Ω/m. However, the number of busbars increases simultaneously, wherein their number is selected such that the specific total resistance of the solar cell, i.e. the specific (area-related) series resistance is lower than 1 Ωcm². This overall results in a reduction of the shadowing caused by the contact, which finally increases the efficiency of the solar cell.

Furthermore, the contact layout can thereby be made more efficiently due to the material, which particularly reduces the material costs and the manufacturing costs associated therewith, in comparison to cost-intensive contact materials, such as Silver.

In particular, it is advantageous to cover the contact fingers and the busbars such that less than 5% of the surfaces of the solar cell are covered. This ensures that the largest portion of the solar cell surface is used for power generation.

Advantageous configurations and improvements result from further dependent claims and from the description with reference to the figures of the drawing.

A preferred improvement provides that the contact finger has a respective line resistance at least 200 Ω/m. Thus, the contact finger can be configured still narrower, which reduces the material costs further.

Preferably, the contact layout is dimensioned such that it has a series resistance of maximum 0.7 Ωcm². Preferably, this is achieved by a particularly favorable layout and by an advantageous number of busbars and/or contact fingers on the semiconductor body and by their particularly favorable geometrical layout in terms of width and layer thickness.

In an advantageous configuration, the contact fingers and/or the busbars are made of an electrically conductive Silver-free material, such as Nickel, Aluminum, Copper, Silicon, Zinc, etc. or alloys thereof. In This case, the contact fingers have a respective width of maximum 100 μm. Due to comparatively low-cost materials, the contact layouts can be produced particularly cost-effectively thereby.

In an alternative, particularly advantageous configuration, the contact fingers are made of Silver or a Silver containing alloy. In This case, the contact fingers have a respective width of maximum 50 μm, whereby the shadow caused by the contact is substantially reduced further. This additionally represents a relatively excellent compromise between a higher electrical conductivity and lower manufacturing costs, since in this case, the material use of comparatively expensive Silver is reduced by the substantially smaller contact structures.

A reduction of the Silver material can also be achieved, if the Silver proportion in the contact finger is reduced and is replaced by another cheaper metal. Alternatively, the contact finger can be designed thinner, narrower, i.e. with smaller cross-section, so that the amount of silver used is reduced thereby.

It has been demonstrated that the optimal width of a contact finger substantially depends on the number of busbars. In particular, the following dependencies result:

| | | Line resistance of | Line resistance of |
|---|---|---|---|
| | Contact | a contact finger | a contact finger |
| Number of | finger width | made of Silver | made of Nickel |
| busbars | [mm] | [Ω/m] | [Ω/m] |
| 5 | 0.06 | 60 | 320 |
| 12 | 0.05 | 85 | 454 |
| 30 | 0.04 | 115 | 614 |

Such contact fingers can be manufactured very cost-effectively based on saving the material or Silver.

In a particularly preferred configuration, the busbars are configured pad-like, as the so-called current collecting pads. Therefore, a current collecting pad contacts at least one contact finger and preferably exactly only one contact finger. Thus, a busbar can be a row of separate contact pads, which are respectively associated to one or more contact fingers, however are isolated from each other individually or in groups, as long as they are not connected by a cell connector. In a specific configuration, the busbar is merely a row of predefined contact positions on the contact fingers, which should be later interconnected at these positions by a cell connector, wherein the contact positions do not show any enlarged surfaces on the contact fingers.

As long as the solar cell is not connected to a cell connector, the series resistance of a solar cell can be measured only with a an adapter, which contacts and connects all contact fingers on the predefined contact positions.

It is particularly advantageous, when the solar cell has at least five busbars. In particular, it has proved to be advantageous when a solar cell has up to 15, 20, or even up to 50 busbars, depending on the design. By the so increased number of the busbars used—depending on the design—the distance between the busbars can be reduced, whereupon the current drawn can be carried off still more efficiently. Thereby, the distance that a charge carrier must cover in a comparatively high ohmic contact finger, reduces, so that the losses caused due to higher line resistance remain comparatively lower.

In an advantageous configuration, each busbar is electrically connected via at least one cell connector. Therefore, the contact surface between the busbar and respective cell connector is at least smaller than the surface of the busbar. The contact surface extends along the longitudinal direction of the busbar. Thus, no additional shadow caused by the cell connector occurs.

Preferably, the contact fingers and the busbars are dimensioned in terms of their number, layout, width and/or layer thickness, such that the product of the line resistance of a contact finger and the line resistance of a busbar is at least 5 Ω²m². Particularly preferably, the product of line resistance of a contact finger and line resistance of a busbar is at least 10 Ω²m² and particularly at least 40 Ω/m².

In a preferred configuration, the contact layout is configured as front-side contact layout for electrical connection of the front side of the semiconductor body.

Preferably, additionally or alternatively, a contact layout is provided as rear side contact layout on the rear side surface of the semiconductor body as well.

A particularly preferred configuration provides that the solar cell is configured as bifacial solar cell. This bifacial solar cell has—besides a front-side contact layout configured according to the invention—also a rear side contact layout for electrical connection of a rear side of the semiconductor body, which is built or disposed preferably identically or at least similar to the front-side contact layout. Bifacial solar cells are the solar cells, in which their front side as well as the rear side are used for power generation. Such solar cells are preferably used, when the solar cell is oriented substantially perpendicular to the earth surface.

Preferably, a bifacial solar cell has a contact in accordance with the invention, on the front side as well as on the rear side.

It is advantageous to electrically connect a solar cell on its rear side of the semiconductor body via a flat rear side contact layer, which has a sheet resistance at least 0.015 Ω/sq. and/or a maximum layer thickness of 20 μm.

In order to reduce the material consumption, it can be further advantageous to reduce the maximum layer thickness of the rear side contact layer to 10 μm, particularly to 5 μm. Advantageously, the contact layout is applied on the solar cell by means of a screen-printing process and/or extrusion printing process and/or ink-jet process and/or plating process. The use of such process has been proved as particularly efficient and cost-effective.

The above configurations and improvements can be combined with each other in any combination, where appropriate. Further possible configurations, improvements and implementations of the invention also include the combinations not explicitly mentioned above or in the following features of the invention described with reference to the exemplary embodiments. In particular, therefore, the skilled person will also add individual elements as improvements or additions to the respective basic form of the present invention.

### TABLE OF CONTENTS OF THE DRAWINGS

The present invention is explained in the following in more details with the help of the exemplary embodiments specified in the schematic figures of the drawings.

Therefore, they show:

FIG. 1A shows a partial top view of a solar cell with front-side contact layout in accordance with the invention;

FIG. 1B shows a partial cross-section of a solar cell with front-side contact layout in accordance with the invention;

FIG. 2 shows a partial perspective cross-sectional representation of a solar cell in accordance with the invention according to another exemplary embodiment;

FIG. 3 shows a partial top view of a solar cell in accordance with the invention according to another exemplary embodiment;

FIG. 4 shows a section on the front side of a solar cell with front-side contact layout according to another exemplary embodiment;

FIG. 4A shows a partial cross-sectional representation of the solar cell according to FIG. 4 along the line A-A;

FIG. 4B shows a partial cross-sectional representation of the solar cell according to FIG. 4 along the line B-B;

FIG. 5 shows another exemplary embodiment of a solar cell in accordance with the invention, with the help of a cross-sectional representation.

The accompanying drawings shall provide a further understanding of the embodiments of the invention. They illustrate embodiments and act in conjunction with the description of the explanation of the principles and concepts of the invention. Other embodiments and many of the mentioned advantages result in regard to the drawings. The elements of the drawings are not necessarily shown to scale with respect to each other.

In the figures of the drawing, the same, functioning similarly and similar looking elements, features and components are provided the same reference numerals, unless detailed otherwise.

### DETAILED DESCRIPTION OF THE FIGURES

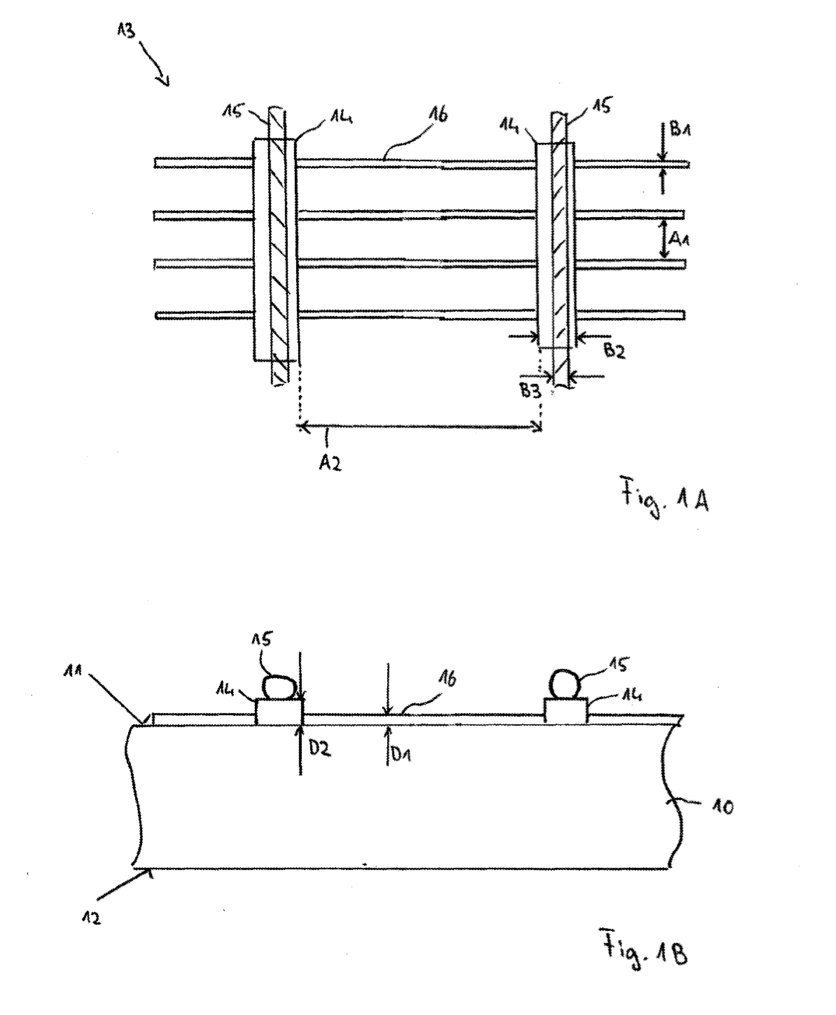

FIGS. 1A and 1B show a partial top view (FIG. 1A) and a cross-sectional representation (FIG. 1B) of a solar cell with front-side contact layout in accordance with the invention.

Therefore, a semiconductor body, for example made of monocrystalline Silicon is indicated by reference numeral 10. The semiconductor body 10 has a front side 11 and a rear side 12. On the front side 11, a front side emitter, not shown here, is disposed in the semiconductor body 10. For the sake of clarity, the p and n-doped areas are within the semiconductor body 10, which are provided for configuring an emitter structure of the solar cell, not represented in the FIGS. 1A and 1B, because these do not represent the core idea of the present invention.

Further, a front-side contact layout 13 is provided on the front side 11. The front-side contact layout 13 includes a plurality of busbars 14, cell connectors 15 and contact fingers 16.

The contact fingers 16 are disposed substantially parallel to each other in the example shown and configure a direct metal-semiconductor contact with the front side surface 11 of the semiconductor body 10.

The contact fingers 16 are configured continuous in the example shown. These contact fingers 16 are used for absorbing the charge carriers, which are generated by an incident light based on the photovoltaic effect on a pn-junction of the front side emitter in the semiconductor body 10. Thus, the contact fingers 16 function as current collecting contacts.

Each of the contact fingers 16 is electrically connected to at least one busbar 14. These busbars 14, which are often also referred to as bus bars and are generally also disposed parallel to each other, are likewise disposed—via a metal-semiconductor contact in the example shown—directly on the front side surface 11 of the semiconductor body 10 and thereby function likewise for absorbing the charge carriers from the semiconductor body 10.

In addition, the busbars 14 also absorb the current flow absorbed via the different contact fingers 16. Thus, the busbars 14 and contact fingers 16 are used for collecting and merging the charge carriers generated in the semiconductor body 10.

In order to transport further the charge carriers so generated and in addition, also to enable an interconnection of the different solar cells disposed adjacently, the so-called cell connectors 15 are provided, which are often also referred to as serial connectors. These cell connectors 15, which are typically not constituents of the actual solar cell but of the solar module, are at least partially disposed on the busbars 14 and firmly bonded to these via an electrically contacting surface. In this way, the current generated from different solar cells of the same solar cell module can be collected and transmitted.

A contact finger 16 has a respective width B1 and a layer thickness D1. The distance of the contact fingers 16 disposed parallel to each other is indicated by A1. In case of Nickel or Aluminum containing contact fingers 16, the width B1 is </=100 μm and in case of Silver containing contact fingers, the width B1 is </=50 μm. The resulting line resistance of the contact finger is greater than 1 Ω/cm.

The width B2 of a busbar 1-4 is here wider than the width B3 of a cell connector 15 disposed thereon, however it would also be possible, if the width B3 is greater than the width B2. The distance of two busbars 14 extending parallel to each other is indicated by A2. Preferably, the width B3 of a cell connector 15 is greater than the width of the corresponding contact surface of the cell connector 15 with respect to the busbar 14.

High conductivity materials such as Silver or Silver containing alloys or comparatively cheaper, however less conductive materials such as Aluminum, Nickel and the like can be used as material for the contact fingers 16 and busbars 14. The contact fingers 16 and busbars 14 are generally manufactured by a strip-like conductive paste applied in the screen-printing process and by sintering of this applied conductive paste. Alternatively, even an extrusion process can be employed. The cell connectors 15 are generally applied on the busbars 14 by soldering.

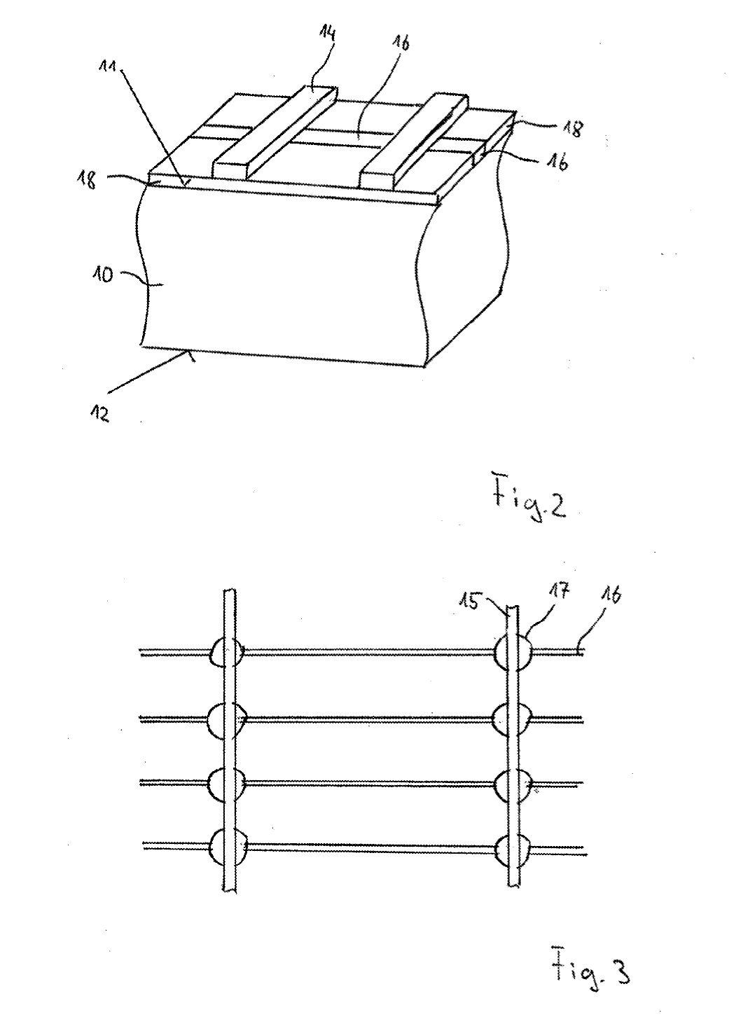

FIG. 2 shows a partial perspective cross-sectional representation of another exemplary embodiment of a solar cell with front-side contact layout in accordance with the invention. Here, a passivation layer 18 is applied over the entire surface 11. In this variant, the busbars 14 are electrically applied not directly on the surface 11 of the semiconductor body 10. Rather, the busbars 14 are applied on the passivation layer 18 and in this way, contact the contact fingers 16 cured in the passivation layer 18.

In the example of FIG. 2, the busbars 14 protrude over the contact fingers 16. This is not required compulsorily. In an improvement, the busbars 14 and contact fingers 16 are processed in a single process step, particularly in a single printing step. In this case, the busbars 14 and contact fingers 16 have the same height (not shown in FIG. 2) respectively.

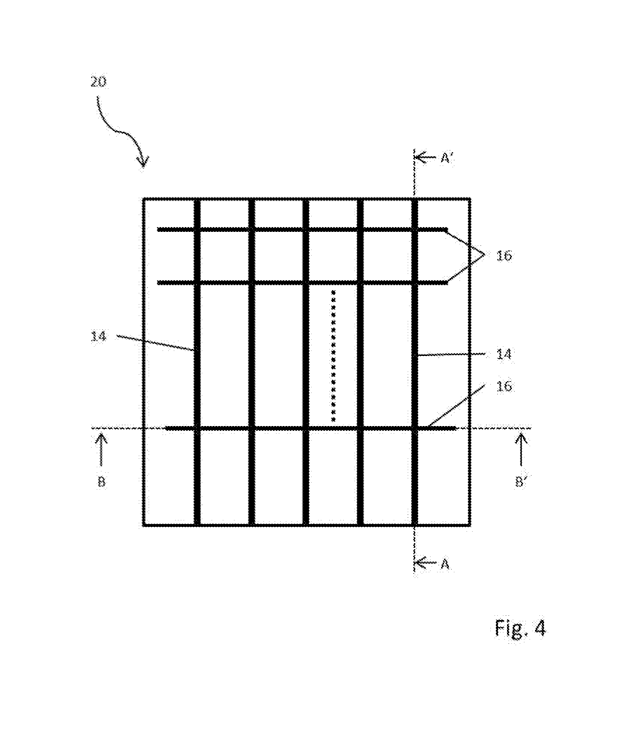

FIG. 3 shows a partial top view of another exemplary embodiment of a solar cell with front-side contact layout in accordance with the invention. In the variant shown in FIG. 3, the busbars 14 are not configured continuous, but pad-like. Therefore, each so-called current collecting pad 17 is electrically connected to a respective contact finger 16.

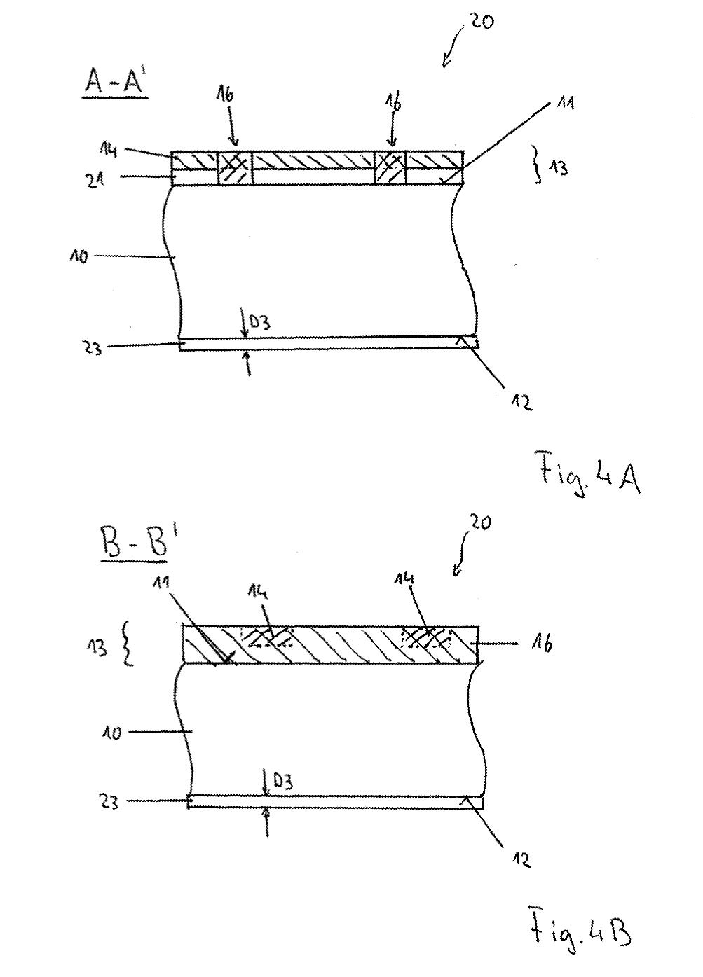

FIG. 4 shows a section on the front side 11 of a solar cell with front-side contact layout 13 in accordance with the invention. The solar cell 20 is indicated there by reference numeral 20. The represented solar cell 20 has a plurality of contact fingers 16, which are electrically interconnected via respective busbars 14.

The contact fingers 16 have a maximum line width B1 </=100 μm in case of using Aluminum and B1 </=50 μm in case of using Silver. A line resistance of each contact finger 16 of at least 100 Ω/m results therefrom. However, by the plurality of five or more busbars 14, which such a solar cell 20 has, the series resistance of the overall solar cell is still kept relatively lower. In particular, the series resistance of the solar cell 20 is maximum 1 Ωcm², which particularly results from using a plurality of busbars 14. Thereby, even by using the contact fingers 16 with relatively high line resistances caused by the relatively short distances, which each charge carrier must cover, the series resistance of the solar cell remains relatively lower.

FIGS. 4A and 4B show a partial cross-sectional representation of the solar cell 20 according to FIG. 4 along the straight lines A-A′ or B-B′.

The solar cell 20 has an antireflection coating 21 applied on the front side 11. This antireflection coating 21 is formed of Silicon nitride in the example shown and used for the purpose of avoiding the reflection of the incident light due to the properties of reflection of the surface of the semiconductor body 10 and thus cannot contribute for charge carrier generation. The contact fingers 16 are generally fired through the antireflection coating 21 and thereby achieve an electrical contact for emitter structure within the semiconductor body 10.

A flat rear side contact layer 23 is provided on the rear side 12 of the semiconductor body 10 in the example of the FIGS. 4A and 4B. Preferably, the rear side contact layer 23 is made of Aluminum or an Aluminum containing alloy, which can be manufactured comparatively cheaper. The thickness D3 of the rear side contact layer 23 is advantageously reduced in order to keep the manufacturing costs as low as possible. Typical values for the thickness D3 of the rear side coating are lower than 20 μm and particularly lower than 10 μm.

In the exemplary embodiment shown with the help of the FIGS. 4A and 4B, the busbars 14 (shaded left) and the contact fingers 16 (shaded right) each have the same height with reference to the front surface 11, so that a predominantly even, planar front side results thereby. Those areas of the contact layout 13, in which the busbars 14 and the contact fingers 16 intersect, are respectively represented cross-hatched in the FIGS. 4A and 4B.

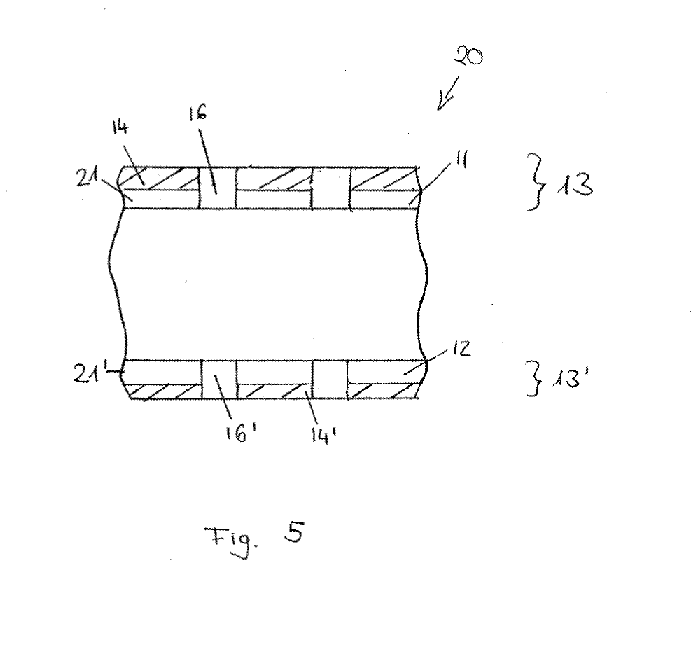

FIG. 5 shows another exemplary embodiment of a solar cell in accordance with the invention with the help of a cross-sectional representation. In the example shown, the solar cell is configured as bifacial solar cell 20. A bifacial solar cell 20 has a predominantly open rear side 12, in this way, similarly in order to use the light incident on the rear side 12 for power generation. The bifacial solar cell 20 has either a passivation layer on the rear side 12 and/or a rear side field (so-called Back-Surface Field, BSF). Therefore, the contact layouts 13, 13′ on the front side 11 and on the rear side 12 preferably have a similar design of their contact fingers 16, 16′ and busbars 14, 14′.

In the example of the FIG. 5, the busbars 14, 14′ (represented shaded) and the contact fingers 16, 16′ each have the same height with reference to the respective surfaces 11, 12, so that a predominantly even, planar front or rear side results thereby.

In bifacial solar cells 20 with p-conducting substrate material (p-Type), the rear side contact layout 13′ can be configured by cheaper Aluminum contacts. Aluminum has a higher electrical resistance (0.027 Ωmm²/m) than Silver (0.016 Ωmm²/m). Until now, in contrast to Silver pastes, the available Aluminum pastes are however not suitable for printing of fine metal contact fingers, because they run wide during printing. Therefore, in such solar cells 20, the problem occurs that the metallized portion of the rear side is too much (typically 20-50%) in order to achieve a favourable efficiency of the rear side.

Therefore, in this exemplary embodiment in FIG. 5, narrow Aluminum contact fingers 16′ with a maximum width of B1′ </=100 μm is printed on the rear side 12 of the bifacial solar cell 20. The contact fingers 16′ of the rear side 12 have a thickness, which can be different from the thickness D1 of the contact fingers of the front side 11. According to the connection of the front side 11, the Aluminum contact fingers 16′ are disposed on the rear side 12.

By the tendency of running of the Aluminum paste, the thickness of the printed contact fingers 16′ in such a low finger width is very limited and a line resistance of at least 100 Ω/m results. By using a large number of busbars 14, for example 5, 10, 15, 20, or 50, the current must cover only a small distance through the comparatively poor conducting Aluminum contact fingers 16′, so that still a series resistance of the solar cell 20 of maximum 1 Ωcm² results.

There are different options to implement such bifacial solar cells 20 contacted via the front and rear side 11, 12:

A preferred configuration provides contact fingers 16 on the front side 11, which are made of Aluminum. The n-type solar cell 20 additionally has a BSF.

In an alternative configuration, a bifacial p-type solar cell is provided, which additionally or alternatively also has contact fingers 16′ on the rear side 12, which are similarly made, for example, of Aluminum.

Another configuration similarly provides a bifacial n-type solar cell with a rear side emitter, in which the contact fingers 16′ of Nickel are made on the rear side.

Although, the present invention was completely described above with the help of preferred exemplary embodiments, it is not restricted to these, but can be modified in many ways.

In the examples shown, the different contact fingers as well as the different busbars extend parallel to each other; however this is not necessary compulsorily. Also, in the examples shown, the busbars are disposed perpendicular to the respective contact fingers; however this is also not necessary compulsorily.

In particular, the invention is also not restricted to the mentioned materials, even if they are occasionally advantageous, such as the use of Silver.

In the same manner, the present invention is also not restricted to the use of p or n-conducting semiconductor materials or p or n-type solar cells. It goes without saying that in more suitable variation, other conducting types and doping concentrations can also be used.

Even the manufacturing processes mentioned are used merely for explanation of the advantages during manufacture; however, the invention shall not be restricted to that effect.

### REFERENCE NUMERALS

10 Semiconductor body, Silicon substrate
11 front side, front-side surface
12 Rear side, rear-side surface
13 (Front side) contact layout
13′ Rear side contact layout
14, 14′ Busbars, Bus bar
15 Cell connector, serial connector
16, 16′ Contact finger
17 Current collecting pad
18 Passivation layer
20 Solar cell
21, 21′ Anti-reflection coatings
23 Rear side contact layer
D1-D3 Layer thicknesses
B1-B3 Widths
A1, A2 Distances

1. Solar cell having a semiconductor body, a contact layout for electrical connection of a surface of the semiconductor body, comprising:
a plurality of current collecting contact fingers, which are disposed substantially parallel to each other, wherein the contact finger has a respective line resistance of at least 100 Ω/m,
a plurality of busbars, which are electrically connected to the contact fingers,
wherein the contact fingers and the busbars are dimensioned, in terms of their material properties, their layout on the semiconductor body, widths and/or their layer thicknesses that the contact layout has a series resistance of maximum 1 Ωcm².

2. Solar cell according to claim 1, wherein the contact finger has a respective line resistance of at least 200 Ω/m.

3. Solar cell according to claim 1, wherein the contact layout has a series resistance of maximum 0.7 Ωcm².

4. Solar cell according to claim 1, wherein the contact fingers and/or the busbars are made of an electrically conductive, silver-free material, wherein the contact fingers have a respective width of maximum 100 μm.

5. Solar cell according to claim 1, wherein the contact fingers are made of Silver or a Silver containing alloy and that the contact fingers have a respective width of maximum 50 μm.

6. Solar cell according to claim 1, wherein the busbars are configured as current collecting pad, wherein the current collecting pad electrically contacts at least one contact finger.

7. Solar cell according to claim 1, wherein at least 5 and/or maximum 50 busbars are provided.

8. Solar cell according to claim 1, wherein each busbar is electrically contacted via at least one cell connector, wherein a contact surface of busbar and corresponding cell connector is at least smaller than the total surface of the busbar and extends along the longitudinal direction of the busbar.

9. Solar cell according to claim 1, wherein the contact fingers and the busbars are dimensioned in terms of their layout, widths and layer thickness such that the product of line resistance of the contact finger and line resistance of the busbar is at least 5 (Ω/m)².

10. Solar cell according to claim 1, wherein the rear side of the semiconductor body is electrically contacted via a flat rear side contact layer, which has a sheet resistance of at least 0.015 Ω/sq. and/or a maximum layer thickness of 20 μm.

11. Solar cell according to claim 1, wherein the rear side contact layer has a maximum layer thickness of 10 μm.

12. Solar cell according to claim 1, wherein the contact layout is produced at least partially by a screen-printing process and/or extrusion printing process and/or inkjet process and/or plating process.

13. Solar cell having a semiconductor body, a contact layout for electrical connection of a surface of the semiconductor body, comprising:
a plurality of current collecting contact fingers, which are disposed substantially parallel to each other, wherein the contact finger has a respective line resistance of at least 100 Ω/m,
a plurality of busbars, which are electrically connected to the contact fingers, wherein the contact fingers and the busbars are dimensioned, in terms of their material properties, their layout on the semiconductor body, their widths and/or their layer thickness, such that the contact layout has a series resistance of maximum 1 Ωcm²,
wherein the contact layout is configured as front side contact layout for electrical connection of a front side and/or as rear side contact layout for electrical connection of a rear side of the semiconductor body.

14. Solar cell according to claim 13, wherein the solar cell is configured as bifacial solar cell, which has a front side contact layout as well a as a rear side contact layout.
